(19) United States
(12) Patent Application Publication
(10) Pub. No.: US 2006/0118878 A1
(43) Pub. Date: Jun. 8, 2006

(54) CMOS device with selectively formed and backfilled semiconductor substrate areas to improve device performance

(75) Inventors: Yi-Chun Huang, Pingihen City (TW); Hun-Jan Tao, HsinChu (TW); Chun-Chieh Lin, Hsinchu (TW); Chih-Hsin Ko, Fongshan City (TW)

Correspondence Address: TUNG & ASSOCIATES;Suite 120, 838 W. Long Lake Road, Bloomfield Hills, MI, 48302, US

(73) Assignee: Taiwan Semiconductor Manufacturing Co., Ltd.

(21) Appl. No.: 11/003,844

(22) Filed: Dec. 2, 2004

(51) Int. Cl. H01L 29/94; H01L 21/8238

(52) U.S. Cl. 257/369; 438/199; 257/374; 438/219

(57) ABSTRACT

An NMOS and PMOS device pair having a selected stress level and type exerted on a respective channel region and method for forming the same, the method including providing a semiconductor substrate; forming isolation regions to separate active areas comprising a PMOS device region and an NMOS device region; lithographically patterning the semiconductor substrate and etching respective recessed areas including the respective NMOS and PMOS device regions into the silicon semiconductor substrate to a predetermined depth; backfilling the respective recessed areas with at least one semiconductor alloy; and, forming gate structures and offset spacers over the respective NMOS and PMOS device regions.

### FIELD OF THE INVENTION

This invention generally relates to formation of MOSFET devices in integrated circuit manufacturing processes and more particularly to a CMOS device and method of forming the same including selectively formed and backfilled recessed semiconductor substrate active area portions to introduce a stress type and level into a channel region of the CMOS device to improve device performance including charge carrier mobility and drive current saturation (I_{Dsat})

### BACKGROUND OF THE INVENTION

Mechanical stresses are known to play a role in charge carrier mobility which affects Voltage threshold (V_{T}) shifts, drive current saturation (I_{Dsat}), and ON/Off current, all critical parameters for efficient and reliable CMOS device operation. The effect of induced mechanical stresses to strain a MOSFET device channel region, and the effect on charge carrier mobility is believed to be influenced by complex physical processes related to acoustic and optical phonon scattering.

In general several conventional manufacturing processes are known to introduce stress into the MOSFET device channel region. For example, stress is typically introduced into the channel region by formation of an overlying polysilicon gate structure and silicide formation processes. In addition, ion implantation and annealing processes typically introduce additional stresses into the polysilicon gate structure which are translated into the underlying channel region altering charge carrier mobility.

Prior art processes have attempted to introduce stresses into the channel region by forming stressed dielectric layers over the polysilicon gate structure following a silicide formation process. These approaches have met with limited success, however, since the formation of particular type of stress (strain), for example compressive or tensile stress in a channel region of one type of majority charge carrier device, for example a PMOS device, will tend to have a degrading effect on a device of the opposite majority charge carrier, e.g., an NMOS device. For example, introducing compressive strain into a device channel region will tend to improve PMOS device performance but degrade NMOS device performance.

Prior art processes have proposed introducing a stressed dielectric layer over the CMOS devices to introduce a selected stress level into a channel region. While these approaches have been shown to be successful, the degrading effect on a device of opposite polarity in dual gate CMOS structures is difficult to overcome, typically requiring a complex series of processing steps. In addition, subsequent manufacturing processes including thermal cycling of the channel region may operate to relax the induced stress (strain) over time, thereby leading to instability and unreliability in device performance.

These and other shortcomings demonstrate a need in the semiconductor device integrated circuit manufacturing art for an improved strained CMOS device and method of manufacturing the same to reliably and selectively introduce a mechanical stress level into CMOS device channel regions to improve device performance and reliability.

It is therefore an object of the present invention to provide an improved strained CMOS device and method of manufacturing the same to reliably and selectively introduce a mechanical stress level into CMOS device channel regions to improve device performance and reliability, while overcoming other shortcomings of the prior art.

### SUMMARY OF THE INVENTION

To achieve the foregoing and other objects, and in accordance with the purposes of the present invention, as embodied and broadly described herein, the present invention provides An NMOS and PMOS device pair having a selected stress level and type exerted on a respective channel region and method for forming the same.

In a first embodiment, the method includes providing a silicon semiconductor substrate; forming isolation regions to separate active areas comprising a PMOS device region and an NMOS device region; lithographically patterning the semiconductor substrate and etching respective recessed areas including the respective NMOS and PMOS device regions into the silicon semiconductor substrate to a predetermined depth; backfilling the respective recessed areas with at least one semiconductor alloy; and, forming gate structures and offset spacers over the respective NMOS and PMOS device regions.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1E are cross sectional schematic views of exemplary portions of a CMOS device including NMOS and PMOS portions at stages of manufacture according to an embodiment of the present invention.

FIGS. 2A-2D are cross sectional schematic views of exemplary portions of a CMOS device including NMOS and PMOS portions at stages of manufacture according to additional embodiments of the present invention.

FIG. 3 is a process flow diagram including several embodiments of the present invention.

### DETAILED DESCRIPTION OF THE PREFERRED EMBODIMENTS

Although the method of the present invention is explained with reference to exemplary NMOS and PMOS MOSFET devices, it will be appreciated that the method of the present invention may be applied to the formation of any CMOS device where a channel region is controllably and selectively strained by selectively backfilling recessed regions formed in a semiconductor substrate including S/D and SDE regions to introduce a selected stress and stress level into a channel region to improve charge carrier mobility.

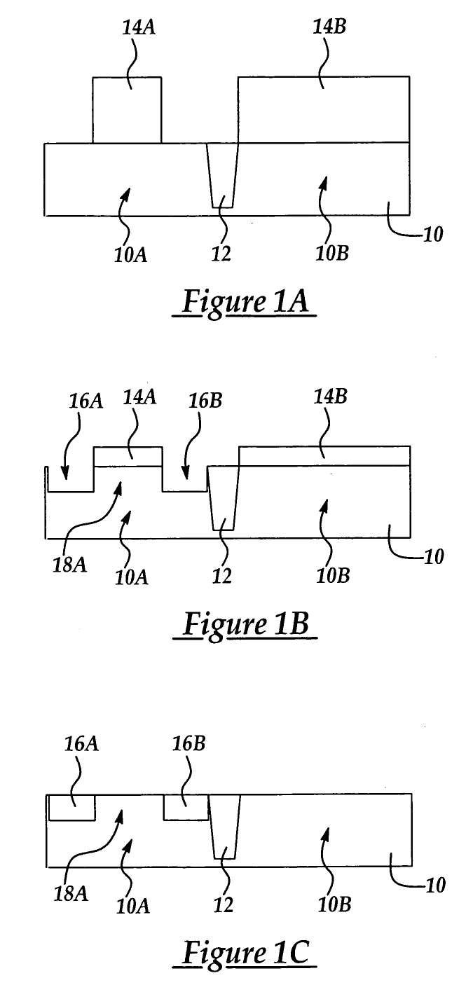

Referring to FIGS. 1A-1E in an exemplary process flow for forming the strained CMOS structures of the present invention, are shown cross-sectional schematic views of a portion of a semiconductor wafer during stages in production of CMOS structures including NMOS and PMOS active regions 10A and 10B.

For example, referring to FIG. 1A is shown a semiconductor substrate, for example a silicon substrate 10 including respective PMOS doped region 10A and NMOS doped region 10B formed by conventional methods, for example a masking process followed by ion implantation and activation with respective N or P type dopants, for example arsenic, phosphorus, and boron. Prior to doping the PMOS and NMOS regions 10A and 10B, isolation regions, for example shallow trench isolation (STI) structures e.g., 12 are formed by conventional processes for example, trench etching and backfilling with an oxide dielectric, followed by planarization.

Still referring to FIG. 1A, in a first exemplary process, the silicon substrate 10, for example arsenic n-doped silicon, is photolithographically patterned by conventional processes to form a resist layer portion 14B covering all of the NMOS region 10B and a resist layer portion 14A covering a portion of the PMOS active region 10A, preferably exposing PMOS region portions disposed adjacent either side of resist layer portion 14A covering a substrate portion over which a gate structure including offset spacers is subsequently formed.

It will be appreciated that the width of the resist portion 14A may vary depending on the desired width of etched recessed areas subsequently formed in exposed substrate portion which are subsequently backfilled with a strained semiconductor alloy. For example the desired width of the recessed areas will depend on the dimensions of a subsequently formed CMOS structure including the gate length and the width of the offset spacers formed adjacent either side the gate structure as shown below. Preferably the etched recessed areas are formed such that at least a source/drain (S/D) region adjacent offset dielectric spacers is encompassed and in one embodiment more preferably including at least a portion of the source drain extension (SDE) regions underlying the offset dielectric spacers but excluding a channel region underlying the gate structure. For example, the distance (width) between the gate edge and the edge of the recessed region may be up to about 1000 Angstroms, more preferably is between about 200 to about 300 Angstroms as further discussed below.

Referring to FIG. 1B, the PMOS substrate portion 10A is then subjected to a conventional silicon etching wet or dry etching process, preferably a dry etching process, to etch first recessed areas e.g., 16A and 16B into the exposed portions of the silicon substrate 10, recessed areas 16A and 16B subsequently encompassing source/drain (S/D) regions in a completed CMOS (PMOS) device. The depth of the recessed areas e.g., 16A and 16B will vary depending on the desired level of stress desired to be subsequently exerted on the area including the channel region e.g., 18A disposed between the recessed areas as explained below, for example up to about 800 Angstroms.

In the first embodiment as shown in FIGS. 1A-1E, when different semiconductor alloys are used to backfill the respectively formed PMOS and NMOS recessed areas having respectively expanded lattice parameters and contracted lattice parameters compared to silicon as explained further below, a recessed depth of up to about 800 Angstroms, more preferably from about 200 to about 400 Angstroms is sufficient to form the desired respective compressive and tensile stresses in the respective channel regions of the PMOS and NMOS devices.

Referring to FIG. 1C, following removal of remaining portion of the resist layer e.g., 14A and 14B portions, a semiconductor alloy comprising silicon and an element having a larger atomic radius is formed to form a first strained silicon composite (alloy), preferably semiconducting, having an expanded lattice cell volume (dimension) compared to silicon is then formed to backfill the first recessed areas 16A and 16B. In a preferred embodiment, the first strained semiconductor alloy composite is formed of SiGe, and is grown in the recessed areas 16A and 16B by a conventional SiGe growth process. It will be appreciated that the upper level of the backfilled material may be formed at about the same level, or slightly above or below the silicon substrate 12 level. e.g., up to about 50 Angstroms. The first strained semiconductor alloy composite advantageously exerts a compressive stress on the silicon substrate area e.g., 18A including a channel region disposed between the backfilled recessed regions 16A and 16B. It will be appreciated that if the first strained semiconductor alloy composite is blanket deposited, for example by a CVD process, that an etchback or CMP process, preferably CMP, may be then carried out to remove material portions overlying the silicon substrate level prior to further processing steps.

Referring to FIG. 1D, similar process steps are then carried out to form recessed areas in the NMOS substrate portion 10B. For example, a second resist layer portions are patterned to form partially covering NMOS region 10B and full covering PMOS region 10A in the same manner as outlined in FIG. 1A and recessed areas e.g., 22A and 22B etched into the NMOS substrate region 10B in the same manner as outlined for forming recessed areas 16A and 16B.

Still referring to FIG. 1D, a second strained silicon composite (alloy), preferably semiconducting, is then formed to backfill the recessed areas 22A and 22B. Preferably, a semiconductor alloy comprising silicon and an element having a smaller atomic radius is formed to have a contracted lattice cell volume (dimension) compared to silicon to backfill the recessed areas 22A and 22B and exert a tensile stress on a channel region included in an area 18B disposed between the recessed areas. In a preferred embodiment, the second strained silicon composite is formed of silicon and carbon, e.g., silicon carbide (e.g., SiC) by a conventional CVD process. A CMP process is then preferably carried out to remove SiC material deposited above the silicon substrate level.

Referring to FIG. 1E, conventional processes are then carried out to form gate oxide portions 24A, 24B polysilicon electrode portions 26A, 26B, and dielectric offset spacers e.g., 28A and 28B, for example formed of oxide and/or nitride. Conventional doping processes, for example ion implantations are carried out to form source/drain extension (SDE) regions e.g., 30A, 30B prior to formation of the offset spacers, and S/D doped regions e.g., 32A included in recessed area e.g., 16A, and e.g., 32B included in recessed area e.g., 22A. As previously discussed, the etched recessed areas e.g., 16A, 16B and 22A, 22B are formed such that at least the S/D regions e.g., 32A, 32B formed in the silicon substrate are encompassed and more preferably including at least a portion of the SDE regions e.g., 30A, 30B underlying dielectric offset spacers e.g., 28A and 28B. For example the distance between the gate edge and the edge of the recessed areas may be up to about 1000 Angstroms, more preferably between about 200 to about 300 Angstroms.

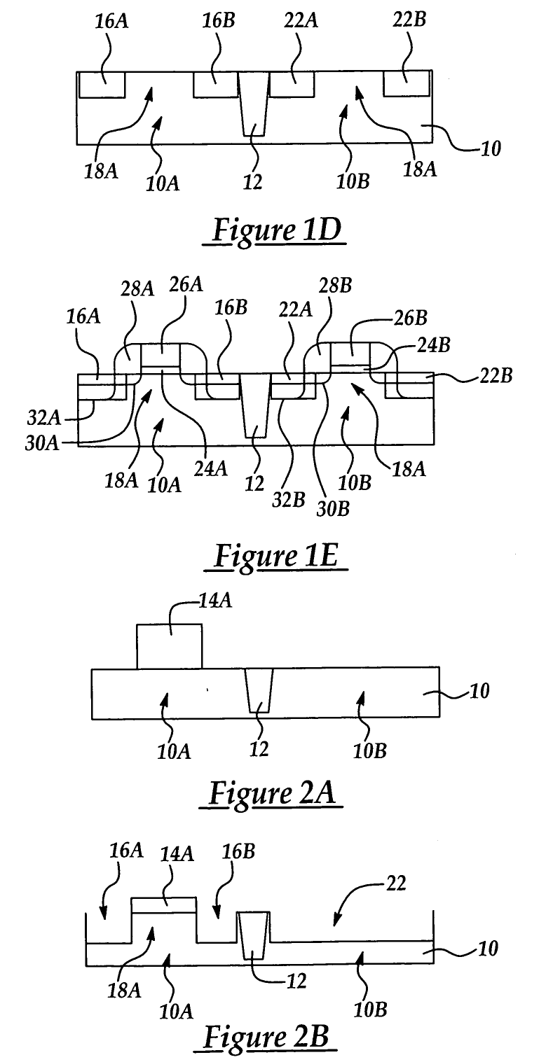

Referring to FIG. 2A, in a second embodiment according to an exemplary process flow, the silicon substrate 10 is for example phosphorous doped and the PMOS region 10A is patterned as previously outlined in FIG. 1A with resist layer portion 14A, however, in this embodiment, the NMOS substrate portion 10B is left exposed.

Referring to FIG. 2B, in a conventional wet or dry etching process, preferably a dry etching process, recessed area portions 16A and 16B are formed as previously outlines in FIG. 1B, however, the NMOS substrate portion 10B is now etched to include the channel region 18B, for example substantially the entire portion of active NMOS region 10B is etched to form a recessed portion 22. In this embodiment, the depth of the recessed area is preferably up to about 800 Angstroms, more preferably having a depth from about 200 to about 600 Angstroms.

Referring to FIG. 2C, following removal of remaining resist layer portions e.g., 14A, a semiconductor alloy comprising silicon and an element having a larger atomic radius is preferably used as the backfilling material to form a strained silicon composite (alloy), preferably semiconducting, having a an expanded lattice volume (dimension) compared to silicon to backfill the first recessed areas 16A, 16B and 22. In a preferred embodiment, the strained silicon composite used to fill the recessed areas formed in the PMOS and NMOS device regions is formed of SiGe in the same manner as previously explained, for example SiGe is grown in the recessed areas 16A, 16B and 22 by a conventional SiGe growth process. Advantageously, in this embodiment, a compressive stress is exerted on the channel region e.g., 18A of the PMOS device by backfilled recessed areas e.g., 16A and 16B, while no stress is exerted on the NMOS channel region e.g., 18B since the backfilled region 22 includes the channel region 18B which is filled with the strained silicon composite.

Still referring to FIG. 2C, conventional processes are then carried out as previously outlined to form gate oxide portions 24A, 24B polysilicon electrode portions 26A, 26B, and dielectric offset spacers e.g., 28A and 28B, for example formed of oxide and/or nitride. Conventional doping processes, for example ion implantations are carried out to form source/drain extension (SDE) regions e.g., 30A,30B prior to formation of the offset spacers, and S/D doped regions e.g., 32A, 32B formed adjacent the dielectric spacers 28A and 28B following offset spacer formation.

Referring to FIG. 2D, in a related embodiment, a mirror process as outlined with respect to FIGS. 2A through 2C is carried out to form a recessed area 16 in PMOS device region 10A including the PMOS channel region, S/D region 32A and SDE regions 30A, and recessed areas 22A and 22B of the NMOS region 10B are formed including the S/D regions 32B and at least a portion of the SDE region 30B as previously outlined. In this embodiment, the backfilling material is preferably a strained semiconductor alloy having a contracted lattice parameter, preferably SiC, which is blanket deposited by a CVD process followed by a CMP process to backfill the respective recessed areas 16, 22A, and 22B. Similar processes as explained in FIG. 2C are then carried out to complete formation of the respective PMOS and NMOS structures. Advantageously, in this embodiment, a tensile stress is exerted on the channel region of the NMOS device while no stress is exerted on the PMOS channel region, having recessed area 16, including the channel region e.g., 18A, filled with the strained semiconductor alloy, e.g., SiC.

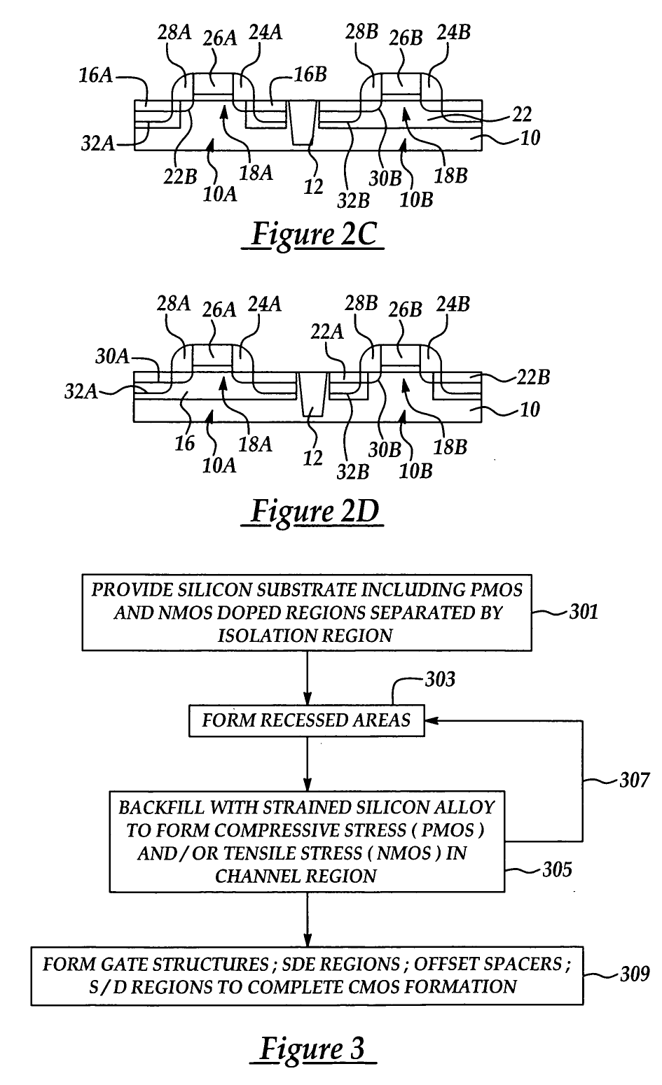

Referring to FIG. 3 is a process flow diagram including several embodiments of the present invention. In process 301, a semiconductor substrate including a doped PMOS portion and doped NMOS portion separated by an isolation region is provided. In process 303, recessed areas are formed in at least one of the NMOS and PMOS regions having a predetermined depth and width including at least a portion of the S/D regions and SDE regions. In process 305, at least one of the NMOS and PMOS recessed areas are backfilled with at least one strained semiconductor alloy to exert at least one of a compressive stress on the PMOS channel area and a tensile stress on the NMOS channel area. As indicated by process directional arrow 307, processes 303 through 305 are optionally repeated in a mirror process to form the same structure in an active region of opposite charge carried polarity. In process 309, CMOS gate structures, SDE doped regions, dielectric offset spacers, and S/D doped regions are formed to complete CMOS formation over the silicon substrate to result in at least one of a compressive stress on the PMOS channel region and a tensile stress on the NMOS channel region. 0031 Thus a PMOS and NMOS device pair and method for forming the same has been presented for adjustably applying a selected stress type and stress level to a channel region of the respective PMOS and NMOS device pair. Advantageously by using a semiconductor alloy with an expanded lattice parameter relative to silicon e.g., SiGe in the PMOS region and a strained semiconductor alloy with a contracted lattice parameter, e.g., SiC in the NMOS device region, a charge carrier mobility and device performance for both PMOS and NMOS devices can be achieved. Further, by including the same strained semiconductor alloy, either having an expanded (e.g., SiGe) or contracted lattice parameter (e.g., Si) in the S/D regions and SDE regions of a device region of a first polarity (e.g., PMOS) while embedding the same strained semiconductor alloy in both the S/D regions, SDE regions, and channel regions of a device region of opposite polarity (e.g., NMOS), the device performance characteristics including drive current saturation in a first device may be advantageously improved while avoiding device degradation in a device of opposite polarity.

The preferred embodiments, aspects, and features of the invention having been described, it will be apparent to those skilled in the art that numerous variations, modifications, and substitutions may be made without departing from the spirit of the invention as disclosed and further claimed below.

1. A method for exerting a selected type and level of stress in a CMOS channel region comprising the steps of:
providing a semiconductor substrate;
forming isolation regions to separate active areas comprising a PMOS device region and an NMOS device region;
lithographically patterning the semiconductor substrate and etching respective recessed areas comprising the respective NMOS and PMOS device regions into the semiconductor substrate to a predetermined depth;
backfilling the respective recessed areas with at least one semiconductor alloy; and,
forming gate structures and offset spacers over the respective NMOS and PMOS device regions.

2. The method of claim 1, wherein the steps of lithographically patterning and backfilling are performed sequentially with respect to the respective NMOS and PMOS device regions.

3. The method of claim 2, wherein the at least one semiconductor alloy comprises a lattice dimension having a relatively larger lattice dimension compared to silicon for backfilling the recessed area comprising the PMOS device region.

4. The method of claim 3, wherein the at least one semiconductor alloy comprises silicon and germanium.

5. The method of claim 2, wherein the at least one semiconductor alloy comprises a lattice dimension having a relatively smaller lattice dimension compared to silicon for backfilling the recessed area comprising the NMOS device region.

6. The method of claim 5, wherein the at least one semiconductor alloy comprises silicon and carbon.

7. The method of claim 2, wherein the recessed areas comprise respective source/drain regions excluding respective channel regions.

8. The method of claim 7, wherein the depths of the recessed areas are from about 200 Angstroms to about 400 Angstroms.

9. The method of claim 7, wherein the recessed areas have a width edge within about 1000 Angstroms of the gate structure edge.

10. The method of claim 7, wherein the recessed areas have a width edge within about 200 to about 300 Angstroms of the gate structure edge.

11. The method of claim 1, wherein the depths of the recessed areas are up to about 800 Angstroms.

12. The method of claim 1, wherein the steps of lithographically patterning and backfilling are performed in parallel with respect to the NMOS and PMOS device regions.

13. The method of claim 12, wherein the recessed area comprising the NMOS device region comprises an NMOS channel region and the recessed area comprising the PMOS device region comprises PMOS source/drain regions excluding a PMOS channel region.

14. The method of claim 13, wherein the NMOS and PMOS recessed areas are backfilled with the at least one semiconductor alloy comprising a lattice dimension relatively larger than silicon.

15. The method of claim 14, wherein the at least one semiconductor alloy comprises silicon and germanium.

16. The method of claim 13, wherein the depths of the recessed areas are from about 200 Angstroms to about 600 Angstroms.

17. The method of claim 12, wherein the recessed area comprising the PMOS device region comprises a PMOS channel region and the recessed area comprising the NMOS device region comprises NMOS source/drain regions excluding a NMOS channel region.

18. The method of claim 17, wherein the NMOS and PMOS recessed areas are backfilled with the at least one semiconductor alloy comprising a lattice dimension relatively smaller than silicon.

19. The method of claim 18, wherein the semiconductor alloy comprises silicon and carbon.

20. An NMOS and PMOS device pair comprising a selected stress level and type in a respective channel region comprising:
a semiconductor substrate comprising an isolation region separating a PMOS device region and an NMOS device region;
the NMOS and PMOS device regions comprising respective recessed areas backfilled with at least one semiconductor alloy to exert one of a compressive and tensile stress on the channel regions of at least one of the respective NMOS and PMOS device regions; and,
gate structures and offset spacers disposed over the NMOS and PMOS device regions to form an NMOS and PMOS device pair.

21. The NMOS and PMOS device pair of claim 20, wherein the recessed areas consist essentially of respective source/drain regions and at least a portion of respective source/drain extension (SDE) regions.

22. The NMOS and PMOS device pair of claim 20, wherein the recessed areas comprise respective source/drain regions excluding respective channel regions.

23. The NMOS and PMOS device pair of claim 21, wherein the at least one semiconductor alloy comprises a lattice dimension having a relatively larger lattice dimension compared to silicon backfilling the recessed area comprising the PMOS device region.

24. The NMOS and PMOS device pair of claim 23, wherein the at least one semiconductor alloy comprises silicon and germanium.

25. The NMOS and PMOS device pair of claim 21, wherein the at least one semiconductor alloy comprises a lattice dimension having a relatively smaller lattice dimension compared to silicon backfilling the recessed area comprising the NMOS device region.

26. The NMOS and PMOS device pair of claim 27, wherein the at least one semiconductor alloy comprises silicon and carbon.

27. The NMOS and PMOS device pair of claim 21, wherein the depths of the recessed areas are from about 200 Angstroms to about 400 Angstroms.

28. The NMOS and PMOS device pair of claim 20, wherein the recessed area comprising the NMOS device region comprises an NMOS channel region and the recessed area comprising the PMOS device region comprises PMOS source/drain regions excluding a PMOS channel region.

29. The NMOS and PMOS device pair of claim 28, wherein the NMOS and PMOS recessed areas are backfilled with a silicon alloy comprising a lattice dimension relatively larger than silicon.

30. The NMOS and PMOS device pair of claim 29, wherein the silicon alloy comprises silicon and germanium.

31. The NMOS and PMOS device pair of claim 20, wherein the recessed area comprising the PMOS device region comprises a PMOS channel region and the recessed area comprising the NMOS device region comprises source/drain regions excluding an NMOS channel region.

32. The NMOS and PMOS device pair of claim 30, wherein the NMOS and PMOS recessed areas are backfilled with a semiconductor alloy comprising a lattice dimension relatively smaller than silicon.

33. The NMOS and PMOS device pair of claim 31, wherein the semiconductor alloy comprises silicon and carbon.

34. An NMOS and PMOS device pair comprising a predetermined stress level and type in a respective channel region comprising:
a semiconductor substrate comprising an isolation region separating a PMOS device region and an NMOS device region;
the PMOS and NMOS device regions comprising respective recessed areas backfilled with at least one semiconductor alloy selected from the group consisting of SiGe and SiC to exert a respective compressive and tensile stress on a respective channel region of at least one of the respective PMOS and NMOS device regions; and,
gate structures and offset spacers disposed over the respective NMOS and PMOS device regions.

35. The NMOS and PMOS device pair of claim 34, wherein the recessed areas consist essentially of respective source/drain regions and at least a portion of respective source/drain extension (SDE) regions.

36. The NMOS and PMOS device pair of claim 34, wherein the recessed areas comprises respective source/drain regions excluding respective PMOS channel regions but including respective NMOS channel regions.

37. The NMOS and PMOS device pair of claim 34, wherein the depths of the recessed areas from about 1 Angstroms to about 800 Angstroms.

38. The NMOS and PMOS device pair of claim 34, wherein the NMOS and PMOS recessed areas are backfilled with a semiconductor alloy comprising SiC.
